(19) United States
(12) Patent Application Publication
(10) Pub. No.: US 2002/0022343 A1
(43) Pub. Date: Feb. 21, 2002

(54) Semiconductor device and method of manufacturing the same

(75) Inventor: Yasunori Nonaka, Nakakoma (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: Fujitsu Quantum Devices Limited, Nakakoma-gun (JP)

(21) Appl. No.: 09/927,403

(22) Filed: Aug. 13, 2001

(30) Foreign Application Priority Data
Aug. 15, 2000 (JP) 2000-246214

(51) Int. Cl. H01L 21/30; H01L 21/46; H01L 21/301; H01L 21/78

(52) U.S. Cl. 438/458; 438/464; 257/183

(57) ABSTRACT

There are contained the steps of forming a plurality of semiconductor elements on surface sides of a plurality of operational unit areas defined on a semiconductor substrate respectively, then connecting the semiconductor elements only in the operational unit areas by wirings, and then forming recesses from the back side of the semiconductor substrate in the situation that a connection layer for connecting mechanically the semiconductor elements only in the operational unit areas is formed on the surface side of the semiconductor substrate, whereby the semiconductor substrate is separated between the semiconductor elements. Accordingly, there is provided a method of manufacturing a semiconductor device having a plurality of semiconductor elements, that is capable of preventing electrical interference between a plurality of semiconductor elements that are connected mutually via wirings and also suppressing variation a width of a recess that separates respective semiconductor elements.

### BACKGROUND OF THE INVENTION

1. Field of the Invention

The present invention relates to a semiconductor device and a method of manufacturing the same and, more particularly, a semiconductor device having a plurality of semiconductor elements and a method of manufacturing the same.

2. Description of the Prior Art

In order to connect a plurality of semiconductor elements mutually, various structures and various methods are employed as follows. There are MESFET (Metal-Semiconductor FET), HEMT (High Electron Mobility Transistor), MISFET (Metal-Insulator-Semiconductor FET), etc. as the semiconductor element.

FIG. 1 shows such a structure that a plurality of mutually independent chip-like semiconductor elements 1a, 1b and 1c are arranged at a predetermined distance on a ceramic substrate 2 and are connected electrically via conductive wires 3 mutually.

FIG. 2 shows such a structure that a plurality of semiconductor elements 5a, 5b and 5c are formed on a semiconductor substrate 4 and these semiconductor elements 5a, 5b and 5c are connected mutually via wirings 6 formed on the semiconductor substrate 4. The integrated semiconductor elements 5a, 5b and 5c shown in FIG. 2 are formed in compliance with the steps shown in FIGS. 3A to 3D, for example.

First, as shown in FIG. 3A, plural operational units U consisting of a plurality of semiconductor elements 5a, 5b and 5c, that are connected mutually via the wirings, are formed on one surface of the semiconductor substrate 4. Then, the one surface of the semiconductor substrate 4 is stuck onto a fixing plate 8 via wax. As the fixing plate 8, the substrate with easy handling and a certain amount of strength, e.g., the ceramic substrate, the glass substrate, or the like may be employed.

Next, as shown in FIG. 3B, a plurality of resist patterns 9 are formed by coating resist on the other surface of the semiconductor substrate 4 and then exposing/developing the resist. These resist patterns 9 cover the back of the operational units U on the semiconductor substrate 4 and are separated mutually at boundary areas between respective operational units U.

Then, as shown in FIG. 3C, while employing the resist patterns 9 as a mask, the semiconductor substrate 4 is etched in the substantially vertical direction up to a depth that exposes the wax 7. Accordingly, the semiconductor substrate 4 is split into plural areas every operational unit U.

And, as shown in FIG. 3D, by removing the resist patterns 9 and the wax 7 from the surface of the semiconductor substrate 4, the semiconductor substrate 4 is separated into the chips. As a result, formation of plural pieces of chip-like semiconductor devices, each having the circuit structure shown in FIG. 2, is completed.

The method of manufacturing the above semiconductor device is set forth in patent application Publication (KOKAI) Hei 8-125077 and patent application Publication (KOKAI) Hei 6-244277, for example.

By the way, as shown in FIG. 1, if a plurality of independent semiconductor elements 1a to 1c are arranged on the ceramic substrate 2 and the semiconductor elements 1a to 1c are connected via the wires 3, an operation for arranging the semiconductor elements 1a to 1c by using the chuck, etc. must be repeated. Therefore, much labors and times for the operation are taken, and thus it is difficult to reduce shorter a chip mounting time. In addition, a margin for arrangement is needed individually when it is going to arrange the semiconductor elements 1a to 1c. Therefore, there is a limit in the shortening distances between the semiconductor elements 1a to 1c.

On the other hand, the critical distances between the semiconductor elements 5a to 5c in the structure shown in FIG. 2 can be reduced to the micron order. However, since the semiconductor elements 5a to 5c are connected via the semiconductor substrate 4, potential fluctuation is propagated between the semiconductor elements 5a to 5c via the semiconductor substrate 4 and then the electrical interference is caused between the semiconductor elements 5a to 5c via the substrate during the high frequency operation. As a result, the gain and the efficiency of the semiconductor element 5a to 5c are reduced. Such problems are ready to occur particularly in the compound semiconductor device.

In patent application Publication (KOKAI) Hei 6-338522 and patent application Publication (KOKOKU) Hei 6-38508, it is set forth that respective semiconductor elements formed in the semiconductor substrate are separated by forming recesses from the front surface side of the semiconductor substrate, and the conductive layer or the dicing sheet is formed on the back surface of the semiconductor substrate. According to such structure, the intervals between the semiconductor element chips can be reduced. However, the connection of the wirings between the semiconductor elements mutually becomes difficult due to the presence of the recesses.

On the contrary, in patent application Publication (KOKAI) Hei 10-22336, it is set forth that the wiring substrate and the semiconductor substrate on which a plurality of semiconductor elements are formed are stuck to each other and then the semiconductor elements are separated by dicing the areas between the semiconductor elements, which are formed on the semiconductor substrate, from the back side of the semiconductor substrate. According to such structure, the electrical interference between a plurality of semiconductor elements via the substrate can be prevented in one functional unit area. However, in order to separate mutually the functional units, it is necessary to cut the wiring substrate in the areas between functional units. Therefore, since the stress is applied to the semiconductor substrate side when the wiring substrate is separated by the dicing, there is easily caused the deviation of the intervals between the semiconductor elements that have been already separated.

### SUMMARY OF THE INVENTION

It is an object of the present invention to provide a semiconductor device capable of preventing electrical interference between a plurality of semiconductor elements that are connected mutually via wirings and also capable of suppressing change of a width of a recess that separates respective semiconductor elements, and a method of manufacturing the same.

According to the present invention, a plurality of semiconductor elements are formed on each of front faces of a plurality of operational unit areas defined in a semiconductor substrate respectively, then the semiconductor elements are connected only in the operational unit area by wirings, and then recesses are formed from the back face of the semiconductor substrate in the situation that a connection layer for connecting mechanically the semiconductor elements together only in the operational unit area is formed on front face of the semiconductor substrate, whereby the semiconductor substrate is divided into a plurality of semiconductor element.

Since the semiconductor elements are connected mechanically and electrically in the operational unit areas by the connection layer and the wirings, the positional relationship between the semiconductor elements in the operational unit area can be maintained mutually by the connection layer and also the semiconductor elements are connected electrically by the wirings after the semiconductor elements are separated.

Therefore, the semiconductor substrate is separated without changing the position of each semiconductor element in respective operational unit areas in the situation that the semiconductor elements are connected by the wirings in the operated unit area, and also the electrical mutual interference between the semiconductor elements via the substrate can be prevented. In addition, since the separation of the semiconductor elements and the substrate division for respective operational unit areas can be carried out by forming the recesses in the semiconductor substrate at the same time, individual separation of the operational unit areas can be facilitated.

Also, according to the present invention, a plurality of semiconductor elements are formed respectively on front surfaces of each a plurality of operational unit areas defined on the semiconductor substrate, then the semiconductor elements are connected only in the operational unit areas by the wirings, then the front face of the semiconductor substrate is stuck onto the fixing substrate via the adhesive agent, then the recesses are formed on the semiconductor substrate between the semiconductor elements to decouple the semiconductor elements, then the metal layer is formed in the decoupled gap between the semiconductor elements in respective operational unit areas and formed on the back face of the semiconductor substrate, and then the semiconductor substrate is peeled off from the fixing substrate by removing the adhesive agent.

According to this, since the decoupled gap in the operational unit areas are filled with the metal layer after the recesses (decoupled gap) are formed on the semiconductor substrate, the later steps can be prevented from varying the width of the recesses. Also, when the semiconductor substrate is peeled off from the fixing substrate while maintaining the mutual positions of the semiconductor elements in the operational unit areas through the metal layer, respective operational unit areas on the semiconductor substrate are naturally separated and thus the new step of cutting the operational unit areas is not needed.

Since one operational unit area corresponds to one semiconductor device and also the metal layer is formed between the semiconductor elements in the operation unit area, the mechanical strength between the semiconductor elements are maintained at the same level as the state before the semiconductor substrate is decoupled. In addition, if the semiconductor device is arranged while grounding the metal layer, the mutual interference of the signal of the semiconductor elements via the substrate can be shielded by the metal layer.

### BRIEF DESCRIPTION OF THE DRAWINGS

FIG. 1 is a plan view showing a connection state of a plurality of semiconductor elements in the prior art;

FIG. 2 is a plan view showing an example of a semiconductor device in the prior art, that has a structure in which a plurality of semiconductor elements are formed on the same substrate;

FIGS. 3A to 3D are sectional views showing the steps of manufacturing a semiconductor device shown in FIG. 2;

FIGS. 4A to 4D are sectional views showing the steps of manufacturing a semiconductor device according to a first embodiment of the present invention;

FIG. 5A is a plan view showing a configuration of one operational unit area shown in FIG. 4A, and

FIG. 5B is a plan view showing the semiconductor device according to the first embodiment of the present invention;

FIGS. 6A and 6B are plan views showing variation of the semiconductor device according to the first embodiment of the present invention;

FIGS. 7A to 7E are sectional views showing the steps of manufacturing a semiconductor device according to a second embodiment of the present invention;

FIG. 8A is a plan view showing a configuration of one operational unit area shown in FIG. 7A, and

FIG. 8B is a plan view showing the semiconductor device according to the second embodiment of the present invention;

FIGS. 9A to 9J are sectional views showing the steps of manufacturing a semiconductor device according to a third embodiment of the present invention;

FIG. 10A is a plan view showing a configuration of one operational unit area shown in FIG. 9A, and

FIG. 10B is a plan view showing the semiconductor device according to the third embodiment of the present invention;

FIGS. 11A to 11E are sectional views showing the steps of manufacturing a semiconductor device according to a fourth embodiment of the present invention;

FIGS. 12A and 12B are plan views showing a variation of the semiconductor device according to the fourth embodiment of the present invention;

FIGS. 13A to 13J are sectional views showing the steps of manufacturing a semiconductor device according to a fifth embodiment of the present invention; and

FIG. 14 is a plan view showing the semiconductor device according to the fifth embodiment of the present invention.

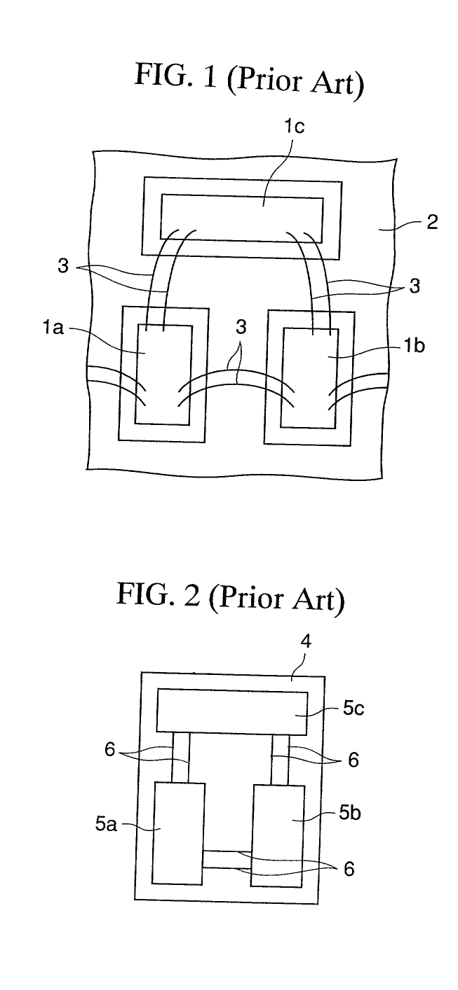

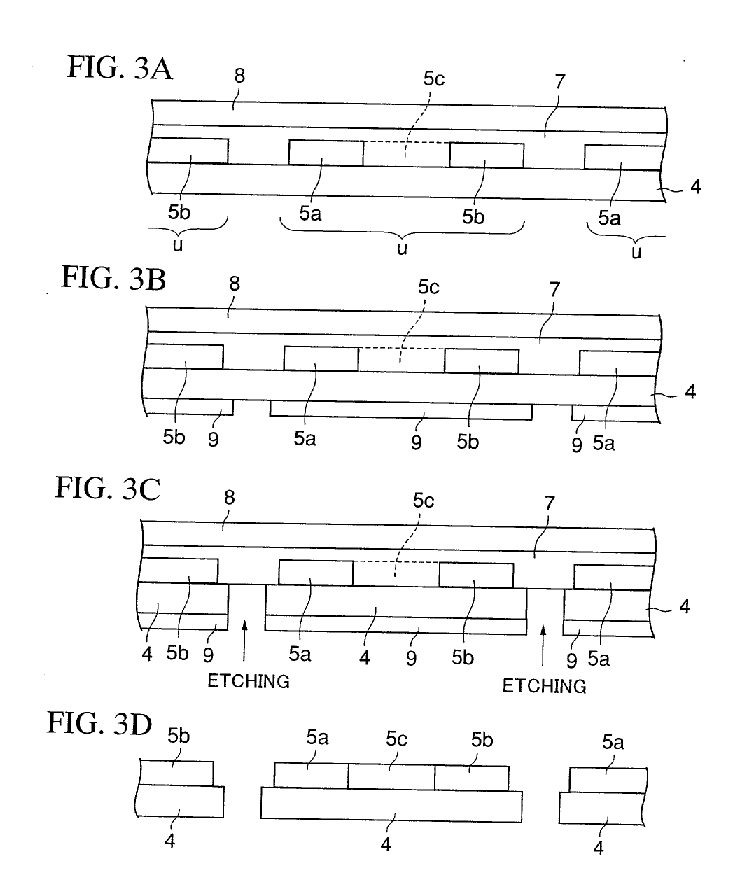

### DESCRIPTION OF THE PREFERRED EMBODIMENTS

Embodiments of the present invention will be explained with reference to the accompanying drawings hereinafter.

(First Embodiment)

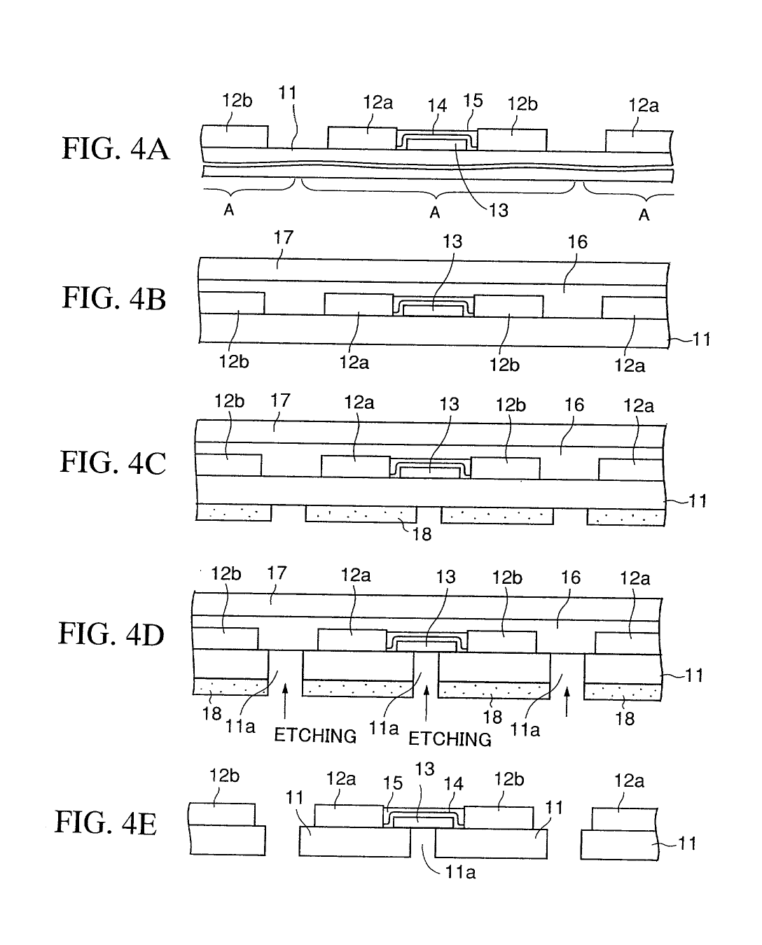

FIGS. 4A to 4D are sectional views showing the steps of manufacturing a semiconductor device according to a first embodiment of the present invention.

First, steps required to get the state shown in FIG. 4A will be explained hereunder.

A plurality of operational unit (functional unit) areas A are defined on one surface of a semi-insulating semiconductor substrate 11 formed of the compound semiconductor such as GaAs, InP, or the like, and then a plurality of semiconductor elements 12a, 12b, 12c are formed every operational unit area A. In one operational unit area A, the semiconductor elements 12a to 12c are formed mutually at an interval of about 40 to 200 μm. As the semiconductor elements 12a to 12c, there are MESFET, HEMT, MISFET, etc.

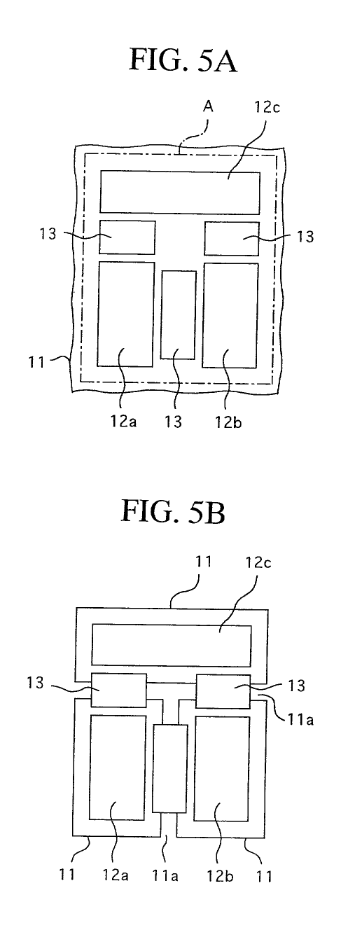

In each operational unit area A, connection films 13 are formed between the semiconductor elements 12a to 12c on the semiconductor substrate 11. Planar surfaces of the connection films 13 have shapes shown in FIG. 5A, for example. In this case, in FIG. 5A, wirings 14 described later are omitted.

The shapes of the connection films 13 are not particularly limited, but they must be separated completely at least between the operational unit areas A. In FIG. 5A, the state is shown wherein the connection film 13 is formed between the semiconductor elements 12a and 12b, 12b and 12c, and 12c and 12a respectively in one operational unit area A.

The connection film 13 is formed of a metal film or an insulating film.

The metal film used as the connection film 13 may be formed by using the vacuum evaporation method, the sputtering method, the selective plating method, or the like. The metal film formed by the vacuum evaporation method or the sputtering method is patterned by the photolithography method, the lift-off method, etc. The selective plating method is the plating method used to form a metal on portions on which the resist patterns are not formed. The metal film may be formed by the same steps as the source/drain electrodes of the FET, for example. Also, it is preferable that an insulating film should be formed between the metal connection film 13 and the semiconductor substrate 11. As such metal film, there are the double-layered film of gold-germanium (AuGe)/gold (Au) or the multi-layered film constructed by laminating a single film or plural films formed of aluminum, copper, tungsten silicide, gold, titanium tungsten, for example. A thickness is several tens nm to several μm when AuGe/Au is employed.

Also, when the connection film 13 is formed of the insulating film, such insulating film is formed by the CVD method and then patterned in a predetermined shape by the photolithography method. As the insulating film, there are employed silicon dioxide, silicon nitride, polyimide, BCB (benzocyclobutyne), etc.

The wirings 14 provided between the semiconductor elements 12a, 12b, 12c formed in the operational unit area A are formed to pass through on the connection film 13 and covered with a protection insulating film 15, for example. In this case, if the connection film 13 is formed of the metal film, the insulating film must be formed between the connection film 13 and the wiring 14.

Next, steps required to get the state shown in FIG. 4B will be explained hereunder.

First, a fixing substrate 17 is pasted onto a surface of the semiconductor substrate 11, on which the semiconductor elements 12a to 12c and connection films 13 are formed, via a wax (adhesive agent) 16. As the fixing substrate 17, there are employed the glass substrate, the silicon substrate, the ceramic substrate, etc., which are easy in handling and have the strength that is hard to deform.

Then, the semiconductor substrate 11 is thinned into a desired thickness, e.g., about 30 μm, by grinding the back surface of the semiconductor substrate 11 by virtue of the mechanical polishing method and the wet etching method.

Then, as shown in FIG. 4C, a plurality of resist patterns 18 are formed by coating the resist on the back surface of the semiconductor substrate 11 and then exposing/developing the resist. These resist patterns 18 have shapes that cover the back surfaces of the semiconductor elements 12a to 12c and are separated mutually at boundary areas between the semiconductor elements 12a to 12c.

Then, as shown in FIG. 4D, separating recesses 11a are formed by etching the semiconductor substrate 11 from the back side in the substantially vertical direction, while using the resist patterns 18 as a mask, until the wax and a bottom surface of the connection film 13 are exposed. In this case, the reactive ion etching (RIE) method is employed as the etching method, and the gas that can etch the semiconductor substrate 11 selectively with respect to the wax 16 and the connection film 13, e.g., the chlorine gas (Cl₂), is employed as the etching gas. The RIE etching is similar in the embodiments described later.

Then, as shown in FIG. 4E, if the semiconductor substrate 11 is released from the fixing substrate 17 by removing the wax 16, the semiconductor elements 12a to 12c that are separated via the separating recesses 11a are split every operational unit area A. In this case, the semiconductor elements 12a to 12c formed in each operational unit area A are brought into the state that they are connected via the connection films 13, and the semiconductor elements 12a to 12c hold the state that they are connected electrically by the wirings 14 formed on the connection films 13. The semiconductor elements 12a to 12c mechanically connected mutually via the connection films 13 have planar shapes shown in FIG. 5B. In FIG. 5B, the wirings 14 are omitted.

The semiconductor elements 12a to 12c connected via the connection films 13 in such manner can be fitted to the circuit board, the electronic device, etc. as they are.

As described above, in the present embodiment, under the condition that the semiconductor elements 12a to 12c connected electrically via the wirings 14 on the same semiconductor substrate 11 are connected mutually via the connection films 13, the semiconductor substrate 11 is separated into parts for the semiconductor elements 12a to 12c.

Accordingly, the mutual interference between the semiconductor elements 12a to 12c via the semiconductor substrate 11 is never caused, and thus the reductions in the gain and the efficiency in the high frequency operation can be suppressed. Also, since the semiconductor elements 12a to 12c are previously connected via the connection films 13 before the semiconductor substrate 11 is separated, the mutual distances between the semiconductor elements 12a to 12c are not varied and are held after the substrate 11 is separated.

These distances can be reduced up to the limit of the photolithography method. Thus, while preventing the electrical mutual interference between the semiconductor elements 12a to 12c via the substrate, the distance between the elements 12a to 12c can be reduced. In addition, since the margin required when the semiconductor elements 12a to 12c are individually arranged respectively is not needed, the distance between the elements 12a to 12c can be reduced smaller than the prior art and also the arrangement area of the chip-like semiconductor elements 12a to 12c can be made small.

In the above embodiment, the separating recesses 11a are formed by the photolithography method. But they may be formed by the dicer, etc. In this case, the distance between the elements is limited by a critical width of the separating recesses 11a formed by the dicer.

It is preferable that the width of the separating recesses 11a formed between the semiconductor elements 12a, 12b, 12c should be set to about 20 to 30 μm.

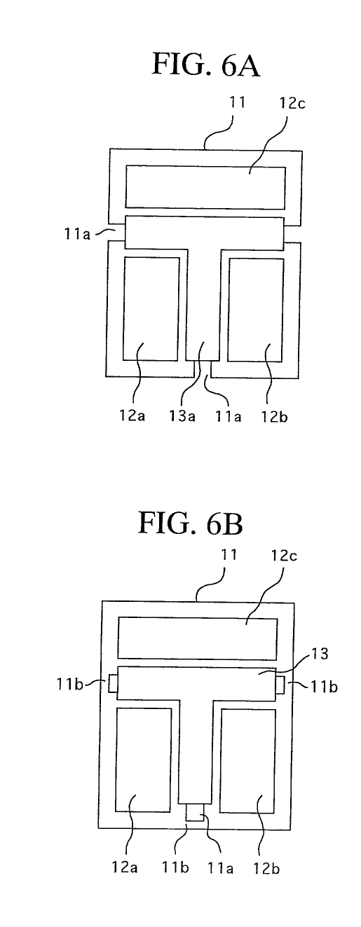

In the above explanation, it is explained to form a plurality of connection films 13 in respective areas between the semiconductor elements 12a to 12c in the operational unit area A. In addition to this, as shown in FIG. 6A, a connection film 13a may be formed continuously in an area between the semiconductor elements 12a to 12c. Further, in FIG. 5B, the semiconductor elements 12a to 12c in the operational unit area A are completely separated by the separating recesses 11a. However, as shown in FIG. 6B, if the separating recesses 11a are not formed in the peripheral area portion of the operational unit area A, the connection strength of respective semiconductor elements 12a to 12c is increased. That is, in FIG. 6B, the semiconductor substrate 11 may be left as a beam portion 11b in the peripheral area portion of the operational unit area A.

(Second Embodiment)

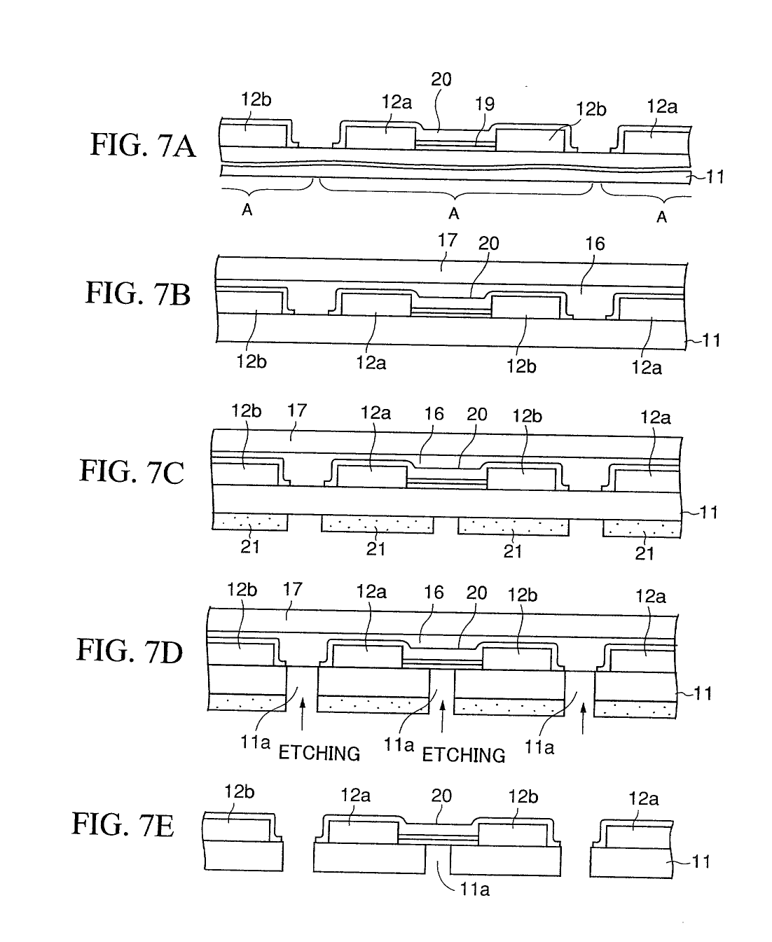

FIGS. 7A to 7E are sectional views showing the steps of manufacturing a semiconductor device according to a second embodiment of the present invention. In this case, the same references as those in FIGS. 4A to 4D denote the same elements in FIGS. 7A to 7E.

First, steps required to get the state shown in FIG. 7A will be explained hereunder.

A plurality of operational unit areas A are defined on one surface of the semi-insulating semiconductor substrate 11 formed of the compound semiconductor such as GaAs, InP, or the like, and a plurality of semiconductor elements 12a to 12c are formed at a predetermined interval in each operational unit area A. Also, the semiconductor elements 12a to 12c are connected via wirings 19 in each operational unit area A.

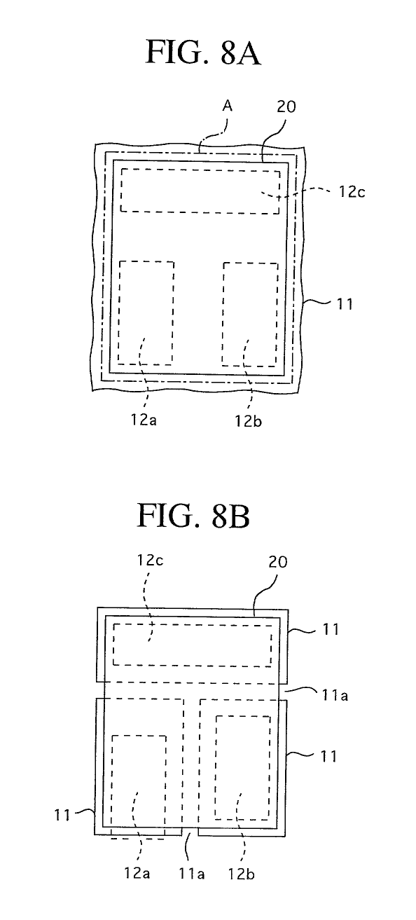

The semiconductor elements 12a to 12c are covered with a insulating surface protection film 20 having a film thickness of 1 to 3 μm in each operational unit area A. The product name PIX manufactured by Hitachi Chemical Co., Ltd., for example, is employed as the material of the surface protection film 20, and the surface protection film 20 is patterned by the dry etching method to be separated between respective operational unit areas A. The planar surface has a shape shown in FIG. 8A. In FIG. 8A, the wirings 19 are omitted.

Then, as shown in FIG. 7B, the fixing substrate 17 is pasted onto the surface of the semiconductor substrate 11 via the wax 16 so as to cover the semiconductor elements 12a to 12c and the surface protection film 20. The fixing substrate 17 is formed of the same material as the first embodiment.

Then, the semiconductor substrate 11 is thinned up to a desired thickness by grinding the back surface of the semiconductor substrate 11 by virtue of the mechanical polishing method and the wet etching method.

Then, as shown in FIG. 7C, a plurality of resist patterns 21 are formed by coating the resist on the back surface of the semiconductor substrate 11 and then exposing/developing the resist. These resist patterns 21 have shapes that cover the back sides of the semiconductor elements 12a to 12c individually and are separated mutually at the boundary areas between the semiconductor elements 12a to 12c.

Then, as shown in FIG. 7D, the separating recesses 11a are formed by etching the semiconductor substrate 11 in the substantially vertical direction from the back side, while using the resist patterns 21 as a mask, until the wax 16 and the surface protection film 20 are exposed. As the etching method, the RIE method is employed.

Then, as shown in FIG. 7E, if the semiconductor substrate 11 is separated from the fixing substrate 17 by removing the wax 16, the semiconductor elements 12a to 12c separated via the separating recesses 11a are split every operational unit area A. In this case, the semiconductor elements 12a to 12c formed in each operational unit area A are brought into the state that they are fixed to the surface protection film 20, and the semiconductor elements 12a to 12c hold the state that they are connected electrically by the wirings 19.

The semiconductor elements 12a to 12c that are covered with one surface protection film 20 have a planar shape shown in FIG. 8B. In FIG. 8B, the wirings 19 are omitted.

The semiconductor elements 12a to 12c that are covered with one surface protection film 20 in such manner can be fitted to the circuit board, the electronic device, etc. as they are.

As described above, in the present embodiment, under the condition that the semiconductor elements 12a to 12c connected electrically via the wirings 19 are covered with the surface protection film 20, the semiconductor substrate 11 is separated into parts for the semiconductor elements 12a to 12c.

Accordingly, the mutual interference between the semiconductor elements 12a to 12c via the semiconductor substrate 11 is never caused, and thus the reductions in the gain and the efficiency in the high frequency operation can be suppressed. Also, since the semiconductor elements 12a to 12c in the operational unit area A are previously fixed by the surface protection film 20 before the semiconductor substrate 11 is cut off, respective distances between the semiconductor elements 12a to 12c are not varied and are held after the semiconductor substrate 11 is separated.

These distances can be reduced up to the limit of the photolithography method. Thus, the arrangement area of the chip-like semiconductor elements 12a to 12c can be made smaller than the prior art by reducing the distances between the elements 12a to 12c, while preventing the electrical mutual interference between the semiconductor elements 12a to 12c via the substrate.

However, since the semiconductor elements 12a to 12c whose mutual positions are fixed by the surface protection film 20 are separated via the separating recesses 11a like the first embodiment, the distance between the elements is limited by the critical width of the separating recesses 11a.

In this case, the semiconductor substrate 11 is cut off by the photolithography method, but the dicer, etc. may be employed.

(Third Embodiment)

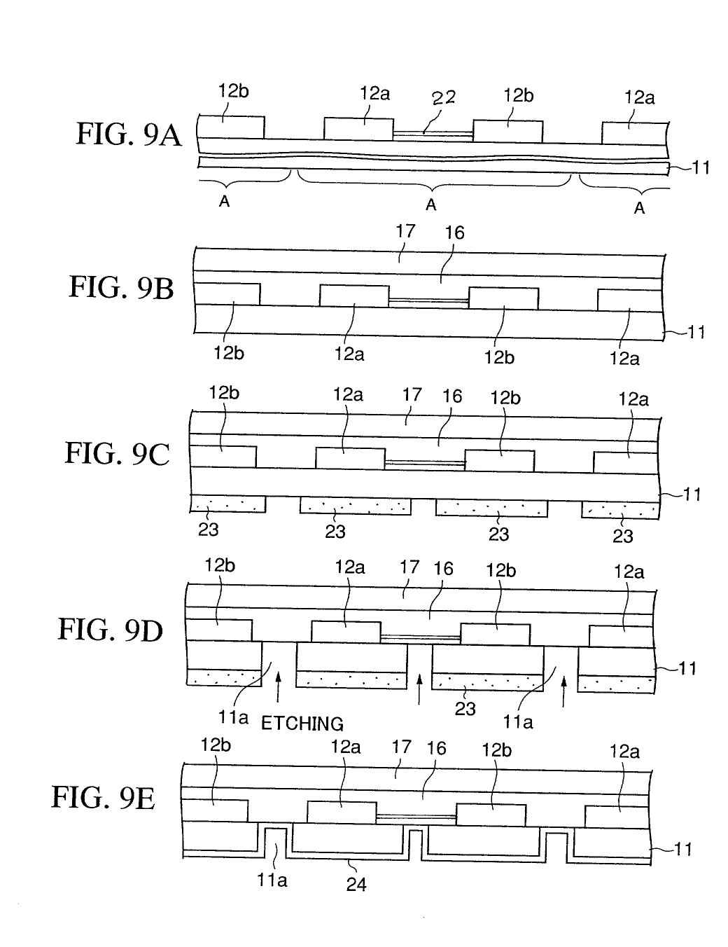

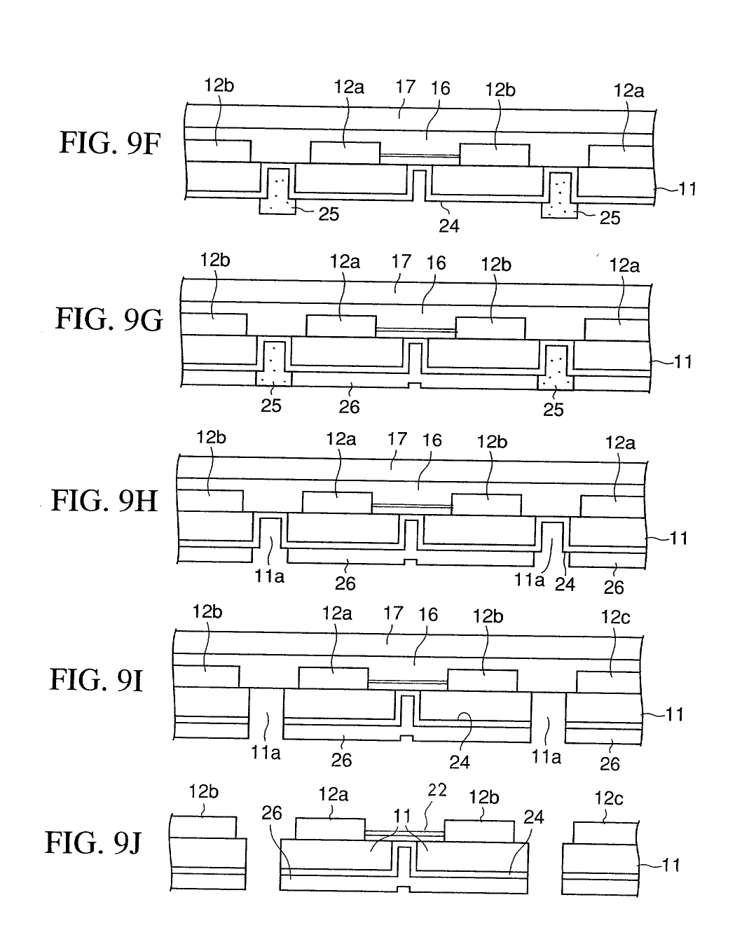

FIGS. 9A to 9J are sectional views showing the steps of manufacturing a semiconductor device according to a third embodiment of the present invention. In this case, the same references as those in FIGS. 4A to 4D denote the same elements in FIGS. 9A to 9J.

First, steps required to get the state shown in FIG. 9A will be explained hereunder.

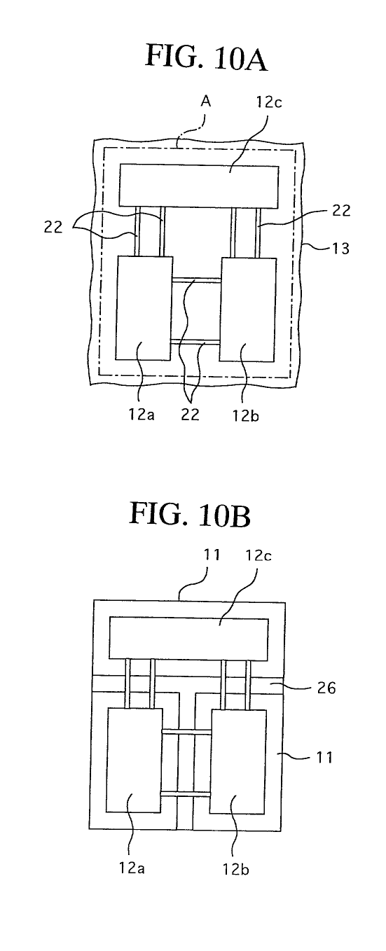

A plurality of operational unit areas A are defined on one surface of the semi-insulating semiconductor substrate 11 formed of the compound semiconductor such as GaAs, InP, or the like, and a plurality of semiconductor elements 12a to 12c are formed at a predetermined interval in each operational unit area A. Also, as shown in FIG. 10A, the semiconductor elements 12a to 12c are connected via wirings 22 in each operational unit area A. These wirings 22 are formed on the semiconductor substrate 11 such that they are sandwiched vertically by insulating films (not shown).

As shown in FIG. 9B, under this condition, the surface of the semiconductor substrate 11 on which the semiconductor elements 12a to 12c are formed is pasted onto the fixing substrate 17 via the wax 16. Then, a thickness of the semiconductor substrate 11 is reduced to a desired thickness by grinding the back surface of the semiconductor substrate 11 by virtue of the mechanical polishing method and the wet etching method.

Then, as shown in FIG. 9C, a plurality of resist patterns 23 are formed by coating the resist on the back surface of the semiconductor substrate 11 and then exposing/developing the resist. Like the first embodiment, these resist patterns 23 have shapes that cover the back surfaces of the semiconductor elements 12a to 12c individually and are separated mutually at boundary areas between the semiconductor elements 12a to 12c.

Then, as shown in FIG. 9D, the separating recesses 11a are formed by etching the semiconductor substrate 11 from the back side in the substantially vertical direction, while using the resist patterns 23 as a mask, until the wax 16 is exposed. In this case, the RIE method is employed as the etching method.

Then, the resist patterns 23 are removed. Then, as shown in FIG. 9E, a seed metal layer 24 that serves as a seed metal for the plating and has a thickness of several hundreds nm is formed on the back surface of the semiconductor substrate 11 and in the separating recesses 11a by the vacuum evaporation method, the sputtering method, or the like. As the seed metal layer 24, a film having a double-layered structure that consists of nickel-chromium (NiCr) as a first layer and gold (Au) as a second layer is employed.

Then, as shown in FIG. 9F, resist 25 is coated on the seed metal layer 24, and then is exposed/developed such that the resist 25 is left only in the separating recesses 11a positioned on the boundary portions between the operational unit areas A.

Then, as shown in FIG. 9G, a metal layer 26 formed of gold and having a thickness of several μm to several tens Am is formed on the seed metal layer 24 by the electrolytic plating method, while using the seed metal layer 24 as an electrode. The metal layer 26 is formed only in the operational unit area A in which the resist 25 is present, but such metal layer 26 is not formed on the peripheral area of the operational unit area A. Then, as shown in FIG. 9H, the resist 25 is removed.

Then, as shown in FIG. 9I, the seed metal layer 24 arranged on the portions that surround the operational unit areas A is removed by the milling method while using the metal layer 26 as a mask. Accordingly, the wax 16 is exposed again through the separating recesses 11a in the peripheral portions of the operational unit areas A. As a result, the semiconductor substrate 11 and the metal layer 26 are brought into the state that they are separated electrically and mechanically every operational unit area A.

Then, as shown in FIG. 9J, if the wax 16 is removed, the semiconductor elements 12a to 12c are separated every operational unit area A and are released individually from the fixing substrate 17 respectively. In this case, since the semiconductor elements 12a to 12c integrated in the operational unit area A are supported by and fixed to one metal layer 26, they still maintain their arrangement relationship prior to the separation and thus are connected electrically by the wirings 22. The semiconductor elements 12a to 12c have planar shapes shown in FIG. 10B. In FIG. 10B, the insulating films formed on and under the wiring 22 are omitted.

As described above, in the present embodiment, the semiconductor elements 12a to 12c formed on the semiconductor substrate 11 are separated in the situation that they are fixed to the fixing substrate 17, and then the back sides of the semiconductor elements 12a to 12c in the operational unit area A are supported by and fixed to one metal layer 26.

Accordingly, when the ground voltage, for example, is applied to the metal layer 26, the potential between the semiconductor elements 12a to 12c is fixed to the same potential as the metal layer 26. Therefore, the mutual interference between the semiconductor elements 12a to 12c via the semiconductor substrate can be eliminated, and thus the reductions in the gain and the efficiency in the high frequency operation can be suppressed.

Also, a plurality of semiconductor elements 12a to 12c are separated in the situation that they are stuck onto the fixing substrate 17, and then they are fixed by the gold plating layer 26. Therefore, the distances between the semiconductor elements 12a to 12c are not varied and the semiconductor elements 12a to 12c are held tightly by the metal layer 26 even after the semiconductor substrate 11 is peeled off from the fixing substrate 17. As a result, these distances can be reduced up to the limit of the width of the separating recesses 11a, and thus the arrangement area of the chip-like semiconductor elements 12a to 12c can be reduced smaller than the prior art. In addition, since the metal layer 26 that is hard to deform is present between the semiconductor elements 12a to 12c and on the back side of the semiconductor substrate 11, the arrangement relationship of the semiconductor elements 12a to 12c is hardly deformed from the initial state if the mechanical vibration, etc. are applied from the outside.

(Fourth Embodiment)

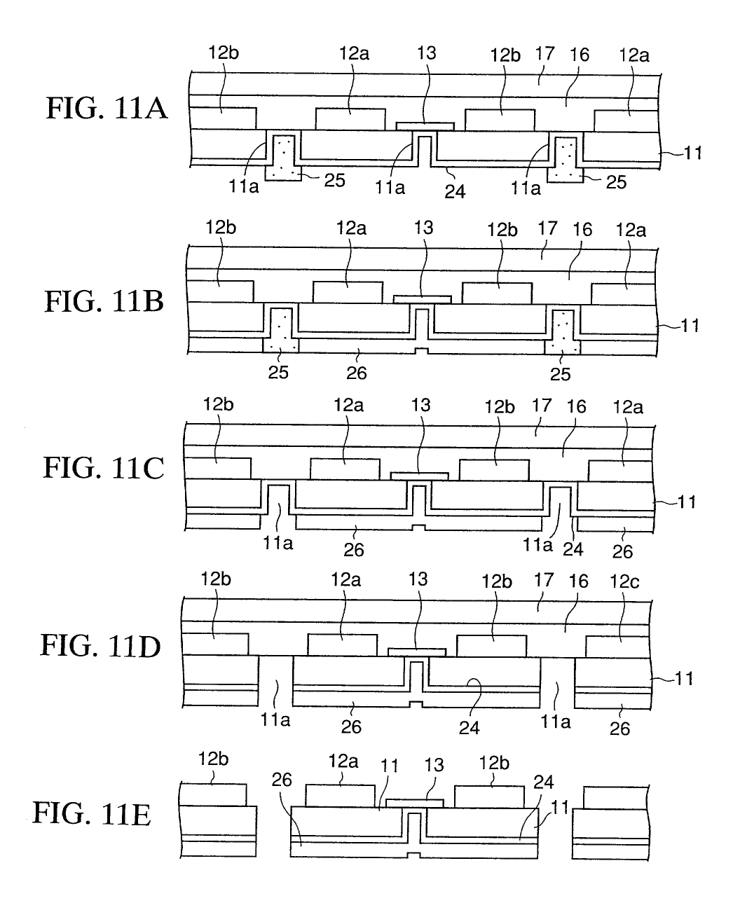

FIGS. 11A to 11E are sectional views showing the steps of manufacturing a semiconductor device according to a fourth embodiment of the present invention. In this case, the same references as those in FIGS. 4A to 4D and FIGS. 9A to 9E denote the same elements in FIGS. 11A to 11E.

In the present embodiment, first the separating recesses 11a are formed between the semiconductor elements 12a to 12c that are formed on one semiconductor substrate 11 along the steps shown in FIGS. 4A to 4D according to the first embodiment. That is, the semiconductor elements 12a to 12c are formed in each operational unit area A on the semiconductor substrate 11, then the semiconductor substrate 11 is stuck onto the fixing substrate 17 via the wax 16, and then the separating recesses are formed between the semiconductor elements 12a to 12c in this state. As a result, the state shown in FIG. 4D is obtained.

Like the first embodiment, the semiconductor elements 12a to 12c are connected mutually in the operational unit area A via the wirings. But the illustration of the wirings is omitted in the present embodiment.

Then, as shown in FIG. 11A, like the third embodiment, the seed metal layer 24 of several hundreds nm thickness is formed on the back surface of the semiconductor substrate 11 and in the separating recesses 11a. Then, the resist 25 is coated on the seed metal layer 24, and then is exposed/developed such that the resist 25 is left in the separating recesses 11a that are located around the operational unit area A.

Then, as shown in FIG. 11B, the metal layer 26 made of gold is formed on the seed metal layer 24 by the electrolytic plating method using the seed metal layer 24 as an electrode. The metal layer 26 is formed only in the operational unit area A in which the resist 25 is present, but such metal layer 26 is not formed in the peripheral area. Then, as shown in FIG. 11C, the resist 25 is removed.

Then, as shown in FIG. 11D, the seed metal layer 24 filled in the separating recesses 11a around the operational unit area A is removed by the milling method using the metal layer 26 as a mask. Accordingly, the wax 16 is exposed again via the separating recesses 11a in the peripheral area of the operational unit area A. As a result, the semiconductor substrate 11 and the metal layer 26 are brought into the state that they are separated electrically and mechanically every operational unit area A.

Then, as shown in FIG. 11E, if the wax 16 is removed, the semiconductor elements 12a to 12c are supported by and fixed to one metal layer 26 in the operational unit area A as one block, and the operational unit areas A are separated and released individually from the fixing substrate 17 respectively. In this case, since the semiconductor elements 12a to 12c integrated in the operational unit area A are supported by and fixed to one metal layer 26, they still maintain their arrangement relationship prior to the separation and thus are connected electrically by the wirings (not shown).

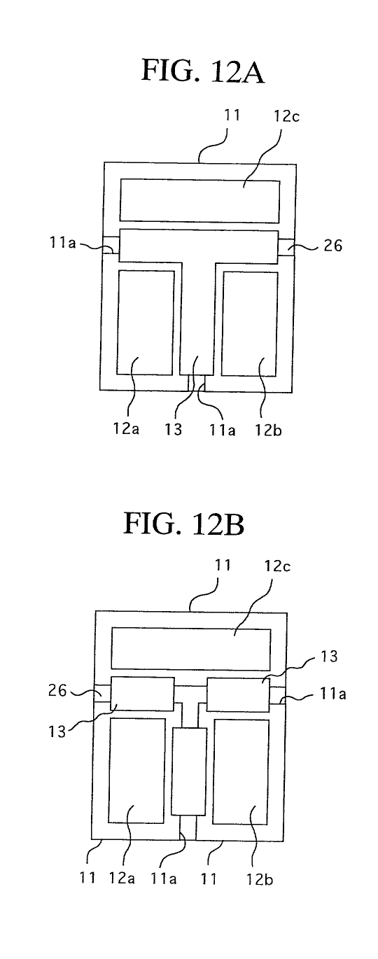

The semiconductor elements 12a to 12c that are fixed to the metal layer 26 have their planar shapes shown in FIGS. 12A and 12B, for example.

As described above, in the present embodiment, like the third embodiment, one gold plating layer 26 is formed in the separating recesses 11a between the semiconductor elements 12a to 12c integrated in the operational unit area A and on the back surfaces of the semiconductor elements 12a to 12c. Therefore, since the semiconductor substrates 11 constituting the semiconductor elements 12a to 12c are electrically separated mutually, the interference via the semiconductor substrates 11 can be eliminated and thus the reductions in the gain and the efficiency in the high frequency operation can be suppressed. Also, in the present embodiment, like the above embodiments, the arrangement area of the chip-like semiconductor elements 12a to 12c can be reduced smaller than the prior art.

In addition, a plurality of semiconductor elements 12a to 12c integrated in the operational unit area A are separated in the situation that they are connected mutually by the connection films 13 and are pasted to the fixing substrate 17. Therefore, mutual deviation of the semiconductor elements 12a to 12c in the operational unit area A can be prevented without fail by the connection films 13 from the formation of the separating recesses 11a to the formation of the metal layer 26. In addition, after the metal layer 26 is formed, a plurality of semiconductor elements 12a to 12c in the operational unit area A are firmly held by the metal layer 26. Therefore, even after they are peeled off from the fixing substrate 17, the distances between the semiconductor elements 12a to 12c can be held and are never changed by the external vibration, etc.

(Fifth Embodiment)

A semiconductor device constructed by employing the above first, second, and third embodiments in combination and a method of manufacturing the same will be explained hereunder.

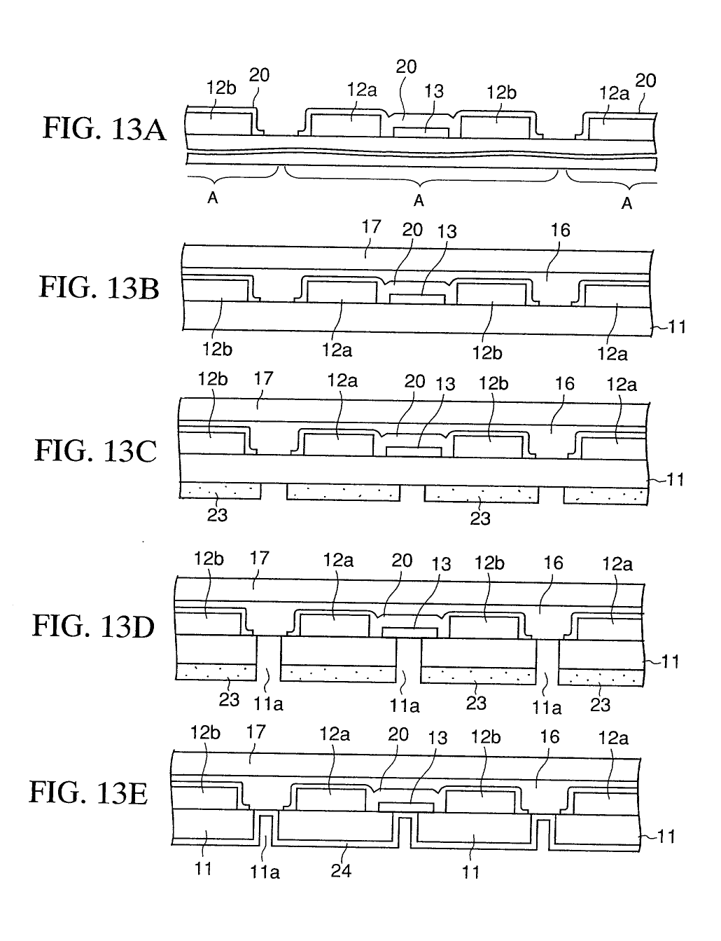

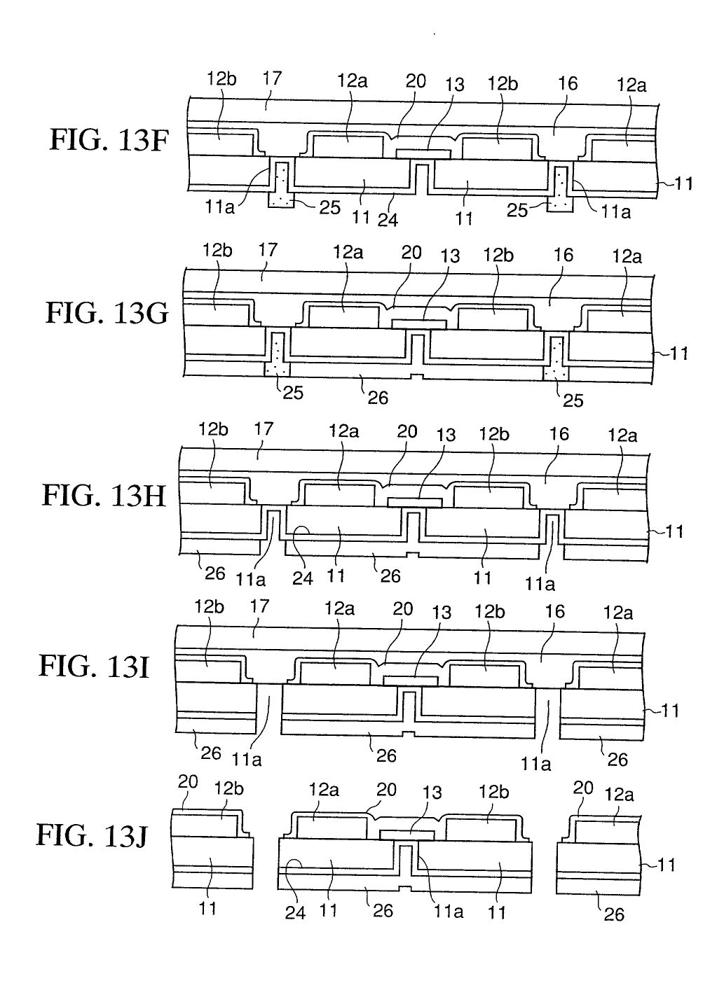

FIGS. 13A to 13J are sectional views showing the steps of manufacturing a semiconductor device according to a fifth embodiment of the present invention. In this case, the same references as those in FIGS. 4A to 4D, FIG. 7A, and FIGS. 9A to 9E denote the same elements in FIGS. 13A to 13J.

First, steps required to get the state shown in FIG. 13A will be explained hereunder.

A plurality of operational unit areas A are defined on one surface of the semiconductor substrate 11, and a plurality of semiconductor elements 12a, 12b, 12c are formed in each operational unit area A. The connection films 13 are formed between the semiconductor elements 12a to 12c in respective operational unit areas A under the same conditions as the first embodiment. Planar surfaces of the connection films 13 have shapes shown in FIG. 5A, for example.

The wirings between the semiconductor elements 12a, 12b, 12c are formed to pass over the connection films 13 and their upper and lower surfaces are sandwiched by the insulating films.

Then, the semiconductor elements 12a to 12c, the connection films 13, and the semiconductor substrate 11 are covered with the surface protection film 20, and then the operational unit areas A are separated by patterning the surface protection film 20. The product name PIX manufactured by Hitachi Chemical Co., Ltd., for example, is employed as the material of the surface protection film 20.

Then, as shown in FIG. 13B, the surface of the semiconductor substrate 11, on which the semiconductor elements 12a to 12c are formed, is stuck onto the fixing substrate 17 via the wax 16.

Then, as shown in FIG. 13C, a plurality of resist patterns 23 are formed by coating the resist on the back surface of the semiconductor substrate 11 and then exposing/developing the resist. These resist patterns 23 have the shapes that cover the back side of the semiconductor elements 12a to 12c on the semiconductor substrate 11 and are separated at the boundary areas between the semiconductor elements 12a to 12c.

Then, as shown in FIG. 13D, the separating recesses 11a are formed by etching the semiconductor substrate 11 in the almost vertical direction from the back side by virtue of the RIE method, while using the resist patterns 23 as a mask, until the wax 17, the connection films 13, and the surface protection film 20 are exposed.

Then, the resist patterns 23 are removed. Then, as shown in FIG. 13E, the seed metal layer 24 that serves as the seed metal for the plating and has a thickness of several hundreds nm is formed on the back surface of the semiconductor substrate 11 and in the separating recesses 11a by the vacuum evaporation method, the sputtering method, or the like. As the seed metal layer 24, like the third embodiment, a film having a double-layered structure that consists of NiCr/Au is employed.

Then, resist 25 is coated on the seed metal layer 24. Then, as shown in FIG. 13F, the resist 25 is exposed/developed such that the resist 25 is left only in the separating recesses 11a positioned around the operational unit area A.

Then, as shown in FIG. 13G, the metal layer 26 formed of gold and having a thickness of several μm to several tens μm is formed on the seed metal layer 24 by the electrolytic plating method, while using the seed metal layer 24 as the electrode.

Then, as shown in FIG. 13H, when the resist 25 is removed, the seed metal layer 24 is exposed from the separating recesses 11a.

Then, as shown in FIG. 13I, the seed metal layer 24 arranged on the portions that surround the operational unit areas A is removed by the milling method, while using the metal layer 26 as a mask.

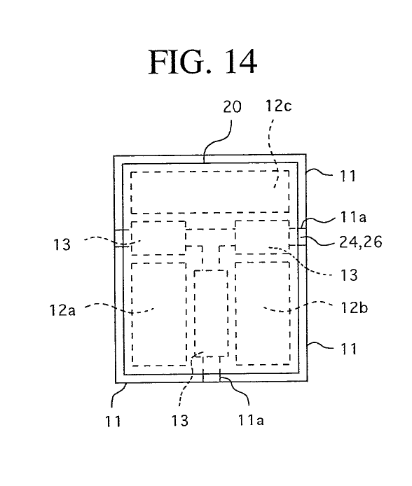

Then, as shown in FIG. 13J, if the wax 16 is removed from the surface of the semiconductor substrate 11, the semiconductor substrate 11 is released as a block of the operational unit area A from the fixing substrate 17 respectively. In this case, since the back side of the semiconductor elements 12a to 12c integrated in the operational unit area A are supported by one metal layer 26, they still maintain their arrangement relationship prior to the separation. The semiconductor elements 12a to 12c fixed to the metal layer 26 have planar shapes shown in FIG. 14.

As described above, in the present embodiment, the semiconductor elements 12a to 12c integrated in the operational unit area A and separated are supported mutually at the back surface side by the metal layer 26, and also they are supported at the surface side by the surface protection film 20. That is, since respective semiconductor elements 12a to 12c are supported to put between the surface protection film 20 and the metal layer 26, such semiconductor elements 12a to 12c are fixed more firmly and thus the mechanical strength between the semiconductor elements 12a to 12c can be enhanced. Also, in the present embodiment, like the above embodiments, the arrangement area of the chip-like semiconductor elements 12a to 12c can be reduced smaller than the prior art.

Further, the surface protection film 20 is raised by the connection films 13 formed between the semiconductor elements 12a to 12c, the upper surface of the surface protection film 20 can be planarized. If the upper surface of the surface protection film 20 is planarized, the stress applied to the surface protection film 20 and the wax 16 when the back surface of the semiconductor substrate 11 is polished can be uniformized. Therefore, the generation of cracks of the semiconductor substrate 11 in the operational unit area A can be more firmly prevented.

According to the present embodiment, it is similar to the first to fourth embodiments that the mutual interference via the semiconductor substrate can be eliminated, and thus the reductions in the gain and the efficiency in the high frequency operation can be suppressed. Also, a plurality of semiconductor elements 12a to 12c integrated in the operational unit area A are separated mutually in the situation that they are connected by the connection films 13 and the surface protection film 20 and are pasted to the fixing substrate 17. Therefore, the displacement of the semiconductor elements 12a to 12c in the separation can be prevented without fail.

In this case, two of the first, second, and third embodiments or more in addition to the above fourth and fifth embodiments may be employed in combination.

Also, in the above embodiments, the semiconductor substrate 11 and the fixing substrate 17 are stuck mutually via the wax 17. But the adhesive agent such as the resist, etc., that can easily removed in the last step, may be employed in place of the wax.

As described above, according to the present invention, a plurality of semiconductor elements are formed on surface sides of a plurality of operational unit areas defined on a semiconductor substrate respectively, then the semiconductor elements are connected only in the operational unit areas by wirings, and then recesses are formed from the back side of the semiconductor substrate in the situation that a connection layer for connecting mechanically the semiconductor elements only in the operational unit areas is formed on the surface side of the semiconductor substrate, whereby the semiconductor substrate is separated. Therefore, after the semiconductor elements are separated, the positional relationship between the semiconductor elements in the operational unit areas can be held mutually by the connection layer and the semiconductor elements are connected electrically by the wirings.

Accordingly, the semiconductor substrate can be separated every semiconductor element not to change the arrangement of the semiconductor elements in respective operational unit areas in the situation that the semiconductor elements are connected by the wirings, and also the electrical mutual interference between the semiconductor elements via the substrate can be prevented. In addition, since the separation of the semiconductor elements and the substrate division for respective operational unit areas can be carried out by forming the recesses in the semiconductor substrate at the same time, individual separation of the operational unit areas can be facilitated.

Also, according to the present invention, a plurality of semiconductor elements are formed respectively on surface sides of a plurality of operational unit areas defined on the semiconductor substrate, then the semiconductor elements are connected only in the operational unit areas by the wirings, then the surface side of the semiconductor substrate is stuck onto the fixing substrate via the adhesive agent, then the recesses are formed on the semiconductor substrate between the semiconductor elements, then the metal layer is formed in the separating recesses between the semiconductor elements in respective operational unit areas and on the back side of the semiconductor substrate, and then the semiconductor substrate is peeled off from the fixing substrate by removing the adhesive agent. Therefore, since the recesses in the operational unit areas are filled with the metal layer after the recesses are formed on the semiconductor substrate, the variation of the width of the recesses by the later steps can be prevented. Also, if the semiconductor substrate is peeled off from the fixing substrate while holding the mutual positions of the semiconductor elements in the operational unit areas by the metal layer, respective operational unit areas on the semiconductor substrate are naturally separated and thus the new step of cutting the operational unit areas is not needed.

What is claimed is:

1. A semiconductor device comprising:
semiconductor elements formed in each operational unit area of a semiconductor substrate;
wirings formed in the operational unit area on the semiconductor substrate via an insulating film to connect the semiconductor elements of each other;
recesses formed from a back face of the semiconductor substrate to have a depth that reaches a bottom of the insulating film, for separating the semiconductor elements; and
a metal layer formed in the recesses and on the back surface of the semiconductor substrate in the operational unit area.

2. A semiconductor device according to claim 1, wherein the semiconductor element is one of MESFET, HEMT, and MISFET.

3. A semiconductor device according to claim 1, wherein a seed metal layer is formed between the semiconductor substrate and the metal layer.

4. A semiconductor device according to claim 1, wherein a connection film is formed on a front area of the semiconductor substrate to connect the semiconductor element of each other.

5. A semiconductor device according to claim 1, wherein an insulating protection film for covering the semiconductor elements is formed, on the semiconductor substrate in the operational unit area.

6. A manufacturing method of a semiconductor device comprising the steps of:
defining operational unit areas on a semiconductor substrate;
forming semiconductor elements in each operational unit area on a front face side of the semiconductor substrate;
forming a connection layer for connecting mechanically the semiconductor elements in respective operational unit areas;
forming wirings for connecting the semiconductor elements in each of the operational unit areas, on the front face side of the semiconductor substrate; and
forming recesses, that disconnect via the semiconductor substrate between the semiconductor elements, from a back face side of the semiconductor substrate, whereby mutual intervals are held by the connection layer and the wirings in the operational unit area and also all connections between the operational unit areas are eliminated.

7. A manufacturing method of a semiconductor device according to claim 6, wherein the connection layer is formed of one of metal material and insulating material.

8. A manufacturing method of a semiconductor device according to claim 6, wherein the connection layer is formed insulating material and covers simultaneously the semiconductor elements only in the operational unit areas.

9. A manufacturing method of a semiconductor device according to claim 6, wherein the recesses are formed in a situation that the front face side of the semiconductor substrate is stuck onto a fixing substrate via an adhesive agent after the wirings and the connection layer are formed, and
the fixing substrate is peeled off from the semiconductor substrate by removing the adhesive agent after the recesses are formed.

10. A manufacturing method of a semiconductor device according to claim 6, wherein forming the semiconductor element is forming one of MESFET, HEMS, and MISFET.

11. A manufacturing method of a semiconductor device comprising the steps of:
defining operational unit areas on a semiconductor substrate;
forming semiconductor elements in each operational unit area on a front face side of the semiconductor substrate;
forming wirings for connecting the semiconductor elements in each of the operational unit areas, on the front face side of the semiconductor substrate via an insulating film; and
sticking the front face side of the semiconductor substrate onto a fixing substrate via an adhesive agent;
forming recesses, that partition the semiconductor substrate for respective semiconductor elements, from a back face side of the semiconductor substrate;
forming a mask in the recesses, that are present in portions to surround the operational unit area, on the back face side of the semiconductor substrate;
forming a metal layer on the back face side of the semiconductor substrate, that is not covered with the mask, and in the recesses between the semiconductor elements in the operational unit area;
removing the mask;
peeling off the semiconductor substrate from the fixing substrate by removing the adhesive agent, whereby the semiconductor substrate is split into respective operational unit areas individually.

12. A manufacturing method of a semiconductor device according to claim 11, wherein the metal layer is formed by an electrolytic plating method.

13. A manufacturing method of a semiconductor device according to claim 12, wherein a seed metal layer formed between the semiconductor layer and the metal layer.

14. A manufacturing method of a semiconductor device according to claim 11 further comprising,
forming a connection layer for connecting mechanically the semiconductor elements in respective operational unit area.

15. A manufacturing method of a semiconductor device according to claim 14, wherein the connection layer is formed of one of metal material and insulating material.

16. A manufacturing method of a semiconductor device according to claim 14, wherein the connection layer is formed insulating material and covers simultaneously the semiconductor elements only in the operational unit area.

17. A manufacturing method of a semiconductor device according to claim 11, wherein the adhesive agent is a wax or a resist.
